(19) United States
(12) Patent Application Publication
(10) Pub. No.: US 2008/0272685 A1
(43) Pub. Date: Nov. 6, 2008

(54) Dispay unit

(75) Inventors: Mitsuharu Ikeda, Kokubunji (JP); Toshiaki Kusunoki, Tokorozawa (JP); Etsuko Nishimura, Hitachiota (JP); Tatsumi Hirano, Hitachinaka (JP); Masatomo Terakado, Chiba (JP); Takahiro Ueno, Mobara (JP); Hiroyasu Yanase, Mobara (JP); Yukio Takasaki, Kawasaki (JP); Takaaki Ogasa, Mobara (JP); Hideyuki Shintani, Mobara (JP)

Correspondence Address: REED SMITH LLP, Suite 1400, 3110 Fairview Park Drive, Falls Church, VA, 22042, US

(73) Assignee: Hitachi, Ltd.

(21) Appl. No.: 12/081,738

(22) Filed: Apr. 21, 2008

(30) Foreign Application Priority Data
Apr. 23, 2007 (JP) 2007-113286

(51) Int. Cl. H01J 1/54; H05K 1/09

(52) U.S. Cl. 313/496; 174/257

(57) ABSTRACT

Hillock is prevented when aluminum wiring is used in order to reduce line resistance in a display unit. The aluminum wiring is formed into multi-layer structure and each layer contains an element which is not solidly solubilized with aluminum. The element are preferably rare earth metal such as Nd, high-melting point transition metals such as Ta and noble metals such as Pd. Intermetallic compounds of aluminum and the element are educed at an interface of the multi-layer wiring and it is prevented that grains of aluminum are enlarged to form hillock.

### INCORPORATION BY REFERENCE

The present application claims priority from Japanese application JP2007-113286 filed on Apr. 23, 2007, the content of which is hereby incorporated by reference into this application.

### BACKGROUND OF THE INVENTION

The present invention relates to a display unit and particularly to aluminum alloy wiring which maintains low resistance and in which interlayer insulative breakdown due to hillock does not occur.

Flat panel displays (FPDs) represented by liquid crystal displays (LCDs), plasma display panels PDPs) and field emission display (FEDs) require low resistance wiring in order to avoid signal delay and increased power consumption due to line resistance.

Aluminum wiring is often used as material having low line resistance, although the aluminum wiring is apt to produce a protrusion 70 named hillock due to annealing such as heating of a substrate upon deposit and the frit-sealing process of panel glass. FIG. 9 shows an example of such a protrusion. When the hillock 70 of FIG. 7 is produced in a bottom electrode of a metal-insulator-metal (MIM) cathode in an FED of FIG. 9 or a thin film transistor (TFT) of a liquid crystal display, for example, an insulator layer 102 disposed between the bottom electrode and an Au/Pt/Ir electrode 101 is broken down, so that short-circuit failure occurs and accordingly the reliability of the device is degraded greatly.

Accordingly, in order to use the aluminum wiring in the display unit, occurrence of the hillock must be prevented. The hillock 70 tends to grow as the heat applied to wiring is higher and the thickness of wiring is thicker and generally, as shown in FIG. 8, the hillock formation suppression method using aluminum alloy containing an additional element 50 such as high-melting point transition metals (Ta (antalum) etc.) or rare earth metal (Nd (neodymium) etc.) is widely used in specifically TFT wiring and MIM cathode of FED.

### SUMMARY OF THE INVENTION

When a display area of the display unit is increased, the thickness of aluminum alloy wiring is increased as the method of avoiding increased power consumption accompanied by increased line resistance, although when the wiring thickness is increased, a grain 60 growing by heating is made large as shown in FIG. 7 and the hillock 70 is apt to grow. Accordingly, the prior art making the additional element 50 contained in the aluminum alloy cannot suppress formation of the hillock 70 with increase of the display area.

FIG. 9 shows an example using aluminum alloy in a bottom electrode 103 of an MIM electron source. In FIG. 9, when the hillock 70 grows in an electron source 100 of an MIM cathode formed on a glass substrate 121, a tunneling insulator 102 between the bottom electrode 103 and an Au/Pt/Ir electrode 101 is broken down to cause occurrence of short-circuit failure. Moreover, in the case of FED, as shown in FIG. 10, a high voltage (near to 10 kV) is applied between an anode plate 130 and a cathode plate 120 disposed in a vacuum as different from other display units in order to make high-energy electrons emitted from the electron source 100 impinge on a fluorescent screen 131 to emit light. Accordingly, when the hillock 70 is formed in a contact electrode 108 made of aluminum alloy, vacuum discharge starting from the hillock 70 occurs in the cathode plate 120 and the anode plate 130 shown in FIG. 10, so that the display unit itself is broken down.

It is an object of the present invention to provide a display unit in which hillock 70 does not occur in wiring so as to realize increase of a display area and improvement of reliability of the display unit.

The present invention is to solve the above problems and concrete measures thereof are as follows.

(1) A display unit includes scan lines extending in a first direction of a display screen and disposed in a second direction perpendicular to the first direction, data lines extending in the second direction of the display screen and disposed in the first direction, insulator film formed between the scan lines and the data lines and pixel electrodes formed in parts enclosed by the scan lines and the data lines. The scan lines or the data lines contain a plurality of aluminum alloy layers and the plurality of aluminum alloy layers contain the same additional element.
(2) In the display unit described in (1), the plurality of aluminum alloy layers contain the same component.
(3) In the display unit described in (2), the thickness of each of the plurality of aluminum alloy layers is thinner than or equal to 300 nm.
(4) In the display unit described in (1), the thickness of each of the plurality of aluminum alloy layers is substantially identical.
(5) In the display unit described in (1), the additional element contained in the plurality of aluminum alloy layers is an element which is not solidly solubilized with aluminum.
(6) In the display unit described in (1), the plurality of aluminum alloy layers contain Nd or another rare earth element.
(7) In the display unit described in (1), the plurality of aluminum alloy layers contain high-melting point transition metals such as Ta, noble metals such as Pd (palladium), or another elements such as Cu (copper) and Si (silicon).
(8) In the display unit described in (1), the plurality of aluminum alloy layers have different orientations.
(9) In the display unit described in (1), the density of the additional element at an interface between first and second aluminum alloy layers of the plurality of aluminum alloy layers is higher than that of the additional element in the first or second aluminum alloy layer.
(10) In the display unit described in (1), a discontinuous interface of a grain boundary is formed at an interface of first and second aluminum alloy layers of the plurality of aluminum alloy layers.
(11) A display unit includes scan lines extending in a first direction of a display screen and disposed in a second direction perpendicular to the first direction, data lines extending in the second direction of the display screen and disposed in the first direction, insulator film formed between the scan lines and the data lines, pixel electrodes and thin film transistors formed in parts enclosed by the scan lines and the data lines, gate electrodes of the thin film transistors connected to the scan lines, source electrodes of the thin film transistors connected to the data lines and drain electrodes of the thin film transistors connected to the pixel electrodes. The gate electrodes of the thin film transistors contain a plurality of aluminum alloy layers and the plurality of aluminum alloy layers contain the same additional element.
(12) In the display unit described in (11), the plurality of aluminum alloy layers contain the same component.
(13) In the display unit described in (11), the thickness of the plurality of aluminum alloy layers is thinner than or equal to 300 nm.
(14) In the display unit described in (11), the additional element contained in the plurality of aluminum alloy layers is an element which is not solidly solubilized with aluminum.
(15) A display unit includes a cathode plate having electron sources formed into a matrix and an anode plate in which a fluorescent screen is formed, and the cathode plate and the anode plate are disposed with predetermined space therebetween. The electron source comprises a bottom electrode formed of a plurality of aluminum alloy layers, a tunneling insulator and an electrode formed of thin film metal layer and the plurality of aluminum alloy layers contain the same additional element.
(16) In the display unit described in (15), the plurality of aluminum alloy layers contain the same component.
(17) In the display unit described in (15), the thickness of the plurality of aluminum alloy layers is thinner than or equal to 300 nm.
(18) In the display unit described in (15), the additional element contained in the plurality of aluminum alloy layers is an element which is not solidly solubilized with aluminum.
(19) A display unit includes scan lines extending in a first direction of a display screen and disposed in a second direction perpendicular to the first direction, data lines extending in the second direction of the display screen and disposed in the first direction, insulator film formed between the scan lines and the data lines and electron sources formed near intersections of the scan lines and the data lines. The electron source includes a bottom electrode formed of aluminum alloy layer, a tunneling insulator and an electrode formed of thin film metal layer and the data lines are connected to the bottom electrodes. The scan lines are connected to the electrodes formed of the thin film metal layers constituting the electron sources through contact electrodes and the contact electrode is formed of a plurality of aluminum alloy layers. The plurality of aluminum alloy layers contain the same additional element.
(20) A display unit includes scan lines extending in a first direction of a display screen and disposed in a second direction perpendicular to the first direction, data lines extending in the second direction of the display screen and disposed in the first direction, insulator film formed between the scan lines and the data lines and pixel electrodes formed in parts enclosed by the scan lines and the data lines. The scan lines or the data lines contain a plurality of aluminum alloy layers and the plurality of aluminum alloy layers are formed by sputtering aluminum alloy target. The plurality of aluminum alloy layers are sputtered at predetermined intervals.
(21) In the display unit described in (20), the sputtering is performed by installing a plurality of targets in a vacuum chamber and moving a substrate of the display unit within the chamber so that sputtering is performed each time the substrate is opposed to the target, so that the plurality of aluminum alloy layers are formed.
(22) In the display unit described in (20), the sputtering is performed by installing a single target in a vacuum chamber and moving a substrate of the display unit within the chamber so that sputtering is performed each time the substrate is opposed to the target, so that the plurality of aluminum alloy layers are formed.
(23) In the display unit described in (20), the sputtering is performed under argon gas partial pressure lower than or equal to 1 Pa.

The effects attained by the above measures are as follows.

According to the measure (1), since wiring is formed of the plurality of aluminum alloy layers containing the same additional element, the line resistance can be suppressed to be low and hillock produced from the aluminum alloy wiring can be prevented.

According to the measure (2), since the plurality of aluminum alloy layers contain the same component, the plurality of aluminum alloy wiring layers can be manufactured easily.

According to the measure (3), since the thickness of each of the plurality of aluminum alloy layers is thinner than or equal to 300 nm, hillock can be suppressed effectively.

According to the measure (4), since the thickness of the plurality of aluminum alloy layers is substantially identical, stress applied to each of the aluminum alloy layers can be uniformed and additionally the manufacturing processes can be simplified.

According to the measures (5) to (7), since the additional element for forming the aluminum alloy is the element which is not solidly solubilized with aluminum, intermetallic compounds can be educed easily and growth of grains of aluminum can be suppressed.

According to the measure (8), since the orientations of the plurality of aluminum alloy layers are different, the diffusion route of aluminum at the interface is disconnected, so that growth of grains of aluminum can be blocked and hillock can be prevented.

According to the measure (9), since the density of the additional element at the interface of the plurality of aluminum alloy layers is high, growth of grains of aluminum over the interface can be blocked, so that the hillock can be prevented.

According to the measure (10), since the discontinuous interface of the grain boundary is formed at the interface of the plurality of aluminum alloy layers, growth of grains of aluminum can be suppressed and hillock can be prevented.

According to the measure (11), since the gate electrodes of the thin film transistors in the active matrix type display unit are formed of the plurality of aluminum alloy layers containing the same additional element, the line resistance of the gate electrodes can be suppressed to be low and hillock from the gate electrodes formed of the plurality of aluminum alloy layers can be suppressed to prevent the insulative breakdown of the gate insulator.

According to the measure (12), since the plurality of aluminum alloy layers constituting the gate electrode contain the same component, the thin film transistors can be manufactured easily.

According to the measure (13), since the thickness of each of the plurality of aluminum alloy layers constituting the gate electrode is thinner than or equal to 300 nm, hillock from the gate electrode can be suppressed effectively.

According to the measure (14), since the plurality of aluminum alloy layers constituting the gate electrode contain the element which is not solidly solubilized with aluminum, eduction of the intermetallic compounds can be made easily and growth of grains of aluminum can be suppressed to prevent hillock of the gate electrode.

According to the measure (15), since the bottom electrode is formed of the plurality of aluminum alloy layers containing the same additional element when the metal-insulator-metal (MIM) is used as the electron source of the field emission display (FED), resistance of the data lines formed by the same process as the bottom electrode can be suppressed to be low and hillock from the bottom electrode in the MIM electron source can be prevented, so that breakdown of the MIM electron source can be prevented.

According to the measure (16), since the plurality of aluminum alloy layers constituting the bottom electrode of the MIM contain the same component, manufacturing of FED is easy.

According to the measure (17), since the thickness of each of the plurality of aluminum alloy layers constituting the bottom electrode of the MIM is thinner than or equal to 300 nm, hillock from the aluminum alloy layers can be suppressed effectively.

According to the measure (18), since the plurality of aluminum alloy layers constituting the bottom electrode of MIM contain the element which is not solidly solubilized with aluminum, eduction of the intermetallic compounds near the interface is made easily and growth of grains of aluminum can be suppressed to prevent hillock of the bottom electrode.

According to the measure (19), since the contact electrode for stably connecting the electron source of MIM and the scan line is formed of the plurality of aluminum alloy layers containing the same additional element, hillock from the contact electrode can be prevented and discharge between the cathode plate and the anode plate of the FED can be prevented even when the total thickness is increased to improve the reliability of connection.

According to the measure (20), since the plurality of aluminum alloy wiring layers are formed by sputtering the target having the same component at predetermined intervals, the plurality of aluminum alloy wiring layers can be deposited easily.

According to the measure (21), since the plurality of targets are installed in a vacuum chamber and the sputtered film is formed when the substrate is moved before the target but the sputtered film is not formed when the substrate is being moved between the targets, the aluminum alloy layers and interface can be formed efficiently.

According to the measure (22), the single target is used and the substrate is moved, so that the same effect as the measure (21) can be attained even by a small-size equipment.

According to the measure (23), since sputtering is performed under argon gas partial pressure lower than or equal to 1 Pa, involution of argon gas can be reduced and the aluminum alloy layers of good quality can be formed.

Other objects, features and advantages of the invention will become apparent from the following description of the embodiments of the invention taken in conjunction with the accompanying drawings.

### BRIEF DESCRIPTION OF THE DRAWINGS

FIG. 1 is a sectional view illustrating multi-layer aluminum alloy wiring according to the present invention;

FIG. 2 is a sectional view illustrating an example of an interface in multi-layer aluminum alloy wiring according to the present invention;

FIG. 3 is a sectional view illustrating an example of an interface in multi-layer aluminum alloy wiring according to the present invention;

FIG. 4 is a sectional view illustrating an example of an interface in multi-layer aluminum alloy wiring according to the present invention;

FIG. 5 is a sectional view illustrating an example of an interface in multi-layer aluminum alloy wiring according to the present invention;

FIG. 6 is a diagram illustrating an example of a method of manufacturing multi-layer aluminum alloy wiring according to the present invention;

FIG. 7 is a diagram illustrating a section of hillock of aluminum;

FIG. 8 is a sectional view illustrating a prior art for suppressing formation of hillock;

FIG. 9 is a diagram illustrating a problem produced when hillock is formed in a bottom electrode;

FIG. 10 is a diagram illustrating a problem produced when hillock is formed in a contact electrode;

FIG. 11 is a sectional view illustrating an embodiment 2;

FIG. 12 illustrates a manufacturing process of an MIM electron source according to the embodiment 2;

FIG. 13 illustrates a manufacturing process of an MIM electron source according to the embodiment 2;

FIG. 14 illustrates a manufacturing process of an MIM electron source according to the embodiment 2;

FIG. 15 illustrates a manufacturing process of an MIM electron source according to the embodiment 2;

FIG. 16 illustrates a manufacturing process of an MIM electron source according to the embodiment 2;

FIG. 17 illustrates a manufacturing process of an MIM electron source according to the embodiment 2;

FIG. 18 illustrates a final manufacturing process of an MIM electron source according to the embodiment 2;

FIG. 19 is a graph showing the dependence on gas pressure of deposit rate and resistivity of Al—Nd (aluminum-neodymium) film formed by sputtering method;

FIG. 20 is a graph showing the dependence on the film thickness per layer of the density of hillocks in number formed in Al—Nd film by annealing in the present invention;

FIG. 21 is a graph showing the dependence on the film thickness per layer of resistivity of Al—Nd film before and after annealing in the present invention;

FIG. 22 is a graph showing a depth profile of an additional element Nd in the present invention;

FIG. 23 is a graph showing the dependence on the film thickness per layer for the orientation of Al—Nd film after annealing in the present invention;

FIG. 24 is a schematic diagram illustrating the interface shape of Al—Nd two-layer film by the electron microscope in the present invention;

FIG. 25 illustrates a manufacturing process of TFT according to the present invention;

FIG. 26 illustrates a manufacturing process of TFT according to the present invention;

FIG. 27 illustrates a manufacturing process of TFT according to the present invention;

FIG. 28 illustrates a manufacturing process of TFT according to the present invention;

FIG. 29 illustrates a manufacturing process of TFT according to the present invention;

FIG. 30 illustrates a final manufacturing process of TFT according to the present invention;

FIG. 31 is a graph showing the dependence on the film thickness per layer of the density of hillocks in number formed in TFT gate wiring by annealing in the present invention;

FIG. 32 is a sectional view illustrating an embodiment 4;

FIG. 33 illustrates a manufacturing process of FED according to the embodiment 4;

FIG. 34 illustrates a manufacturing process of FED according to the embodiment 4;

FIG. 35 illustrates a manufacturing process of FED according to the embodiment 4;

FIG. 36 illustrates a manufacturing process of FED according to the embodiment 4;

FIG. 37 illustrates a manufacturing process of FED according to the embodiment 4;

FIG. 38 illustrates a manufacturing process of FED according to the embodiment 4;

FIG. 39 illustrates a final manufacturing process of FED according to the embodiment 4; and

FIG. 40 is a graph showing the dependence on the film thickness per layer of the frequency of discharges of the display unit according to the embodiment 4 of the present invention.

### DESCRIPTION OF THE EMBODIMENTS

### Embodiment 1

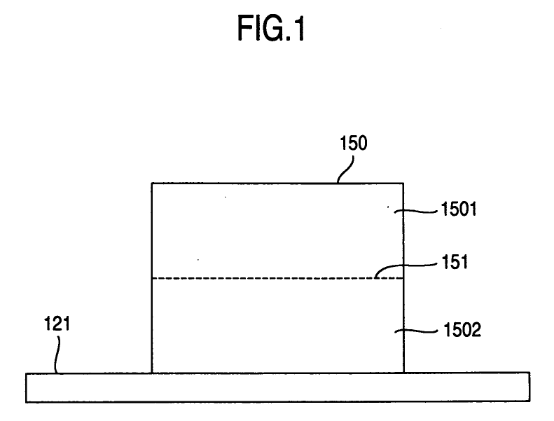

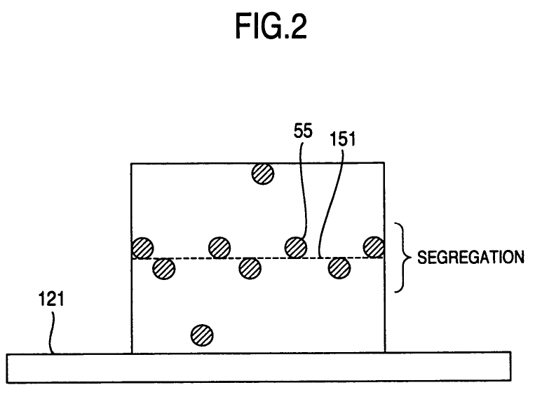

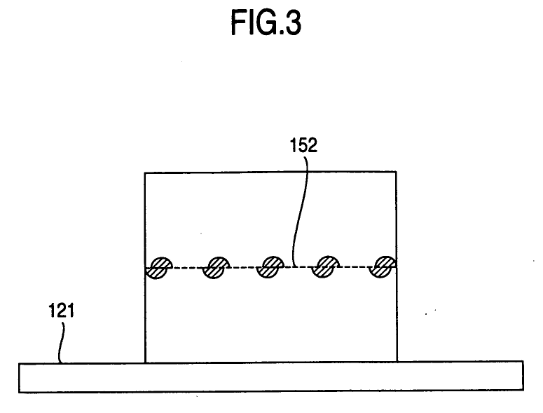

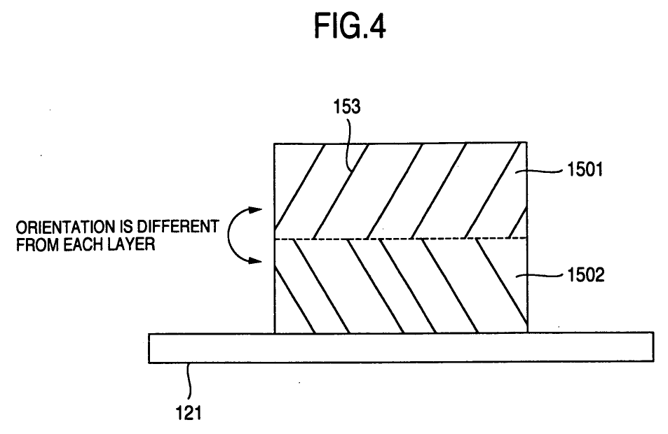

FIG. 1 illustrates two-layer wiring formed of two aluminum alloy layers fabricated on a substrate. An interface 151 is formed between a top layer 1501 and a bottom layer 1502. The top and bottom layers 1501 and 1502 contain the same additional element. As shown in FIG. 2, intermetallic compounds 55 of the additional element and aluminum are segregated at the interface 151 of the two layers. Moreover, as shown in FIG. 3, a discontinuous interface of a grain boundary is formed at the interface 151. Furthermore, as shown in FIG. 4, the top layer 1501 and the bottom layer 1502 of the two-layer wiring between which the interface 151 is formed have orientations 153 different from each other.

The top and bottom layers 1501, 1502 of the two-layer wiring have the substantially same thickness which is thinner than or equal to 300 nm. Since the two-layer wiring is formed of a plurality of aluminum alloy layers containing the same additional element 50, formation of the hillock 70 in wiring can be suppressed even if it is subjected to the annealing.

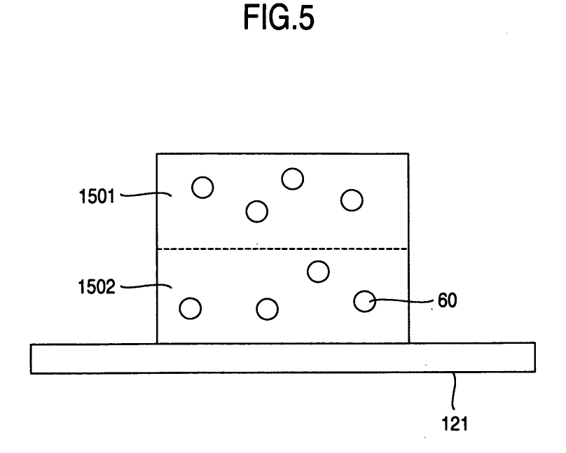

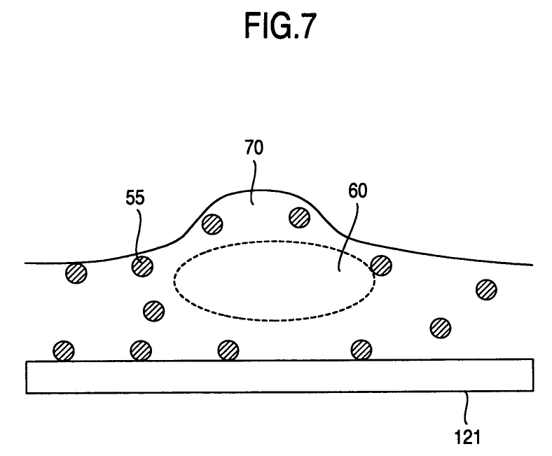

An element which is not solidly solubilized with aluminum is effective as the additional element 50. The reason using the element which is not solidly solubilized is that the lower the solid solubility of the additional element 50 is, the easier the additional element 50 is educed and it is effective that the additional element 50 is segregated at the interface 151 by migration upon sputtering. Concretely, the additional element 50 may be not only rare earth elements such as Nd and Ce but also high melting point transition metals such as Ta, noble metals such as Pd and Cu, Si, etc. The rare earth elements such as Nd among them is particularly effective since intermetallic compounds of aluminum and the elements are produced and educed at low temperature, for example, eduction is made at about 300° C. in case of Nd, whereas eduction is made at about 475° C. in case of Ta of the high melting point transition metals, for example. Moreover, as shown in FIG. 5, the diameter of grains 60 is further desirably made substantially identical in the layers. Since the hillock 70 is considered to be caused by growth of aluminum grain as shown in FIG. 7, it is considered that the growth of the aluminum grain can be suppressed by the structure of the embodiment.

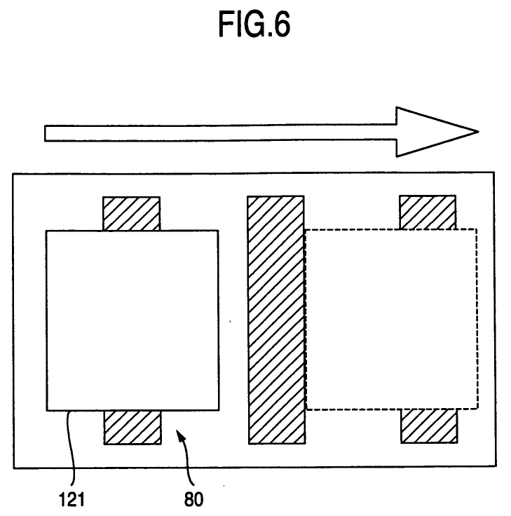

The multi-layer film of the embodiment is formed by sputtering. More particularly, as shown in FIG. 6, a plurality of sputter targets 80 of aluminum alloy are prepared. Sputtering is performed in a vacuum smaller than or equal to 1 Pa. This reason is that argon (Ar) or the like is prevented from being involved in a sputter film. The substrate 121 is made to pass before the sputter targets 80. A sputter film is formed on the substrate before the sputter target 80 and any film is not formed until a next sputter target 80 is reached. A sputter film is formed at a next sputter target 80 again. The interface 151 as described above is formed between the first and second sputter films.

Formation of the film in the embodiment is not required to use a relatively large-scale continuous deposition apparatus having the plurality of sputter target 80 disposed as described above. For example, a single sputter target 80 may be prepared to thereby form a first sputter film by sputtering and then move the substrate 121 from the place in which the sputter target 80 is located. After a predetermined time, the substrate 121 may be moved to be installed before the sputter target 80 to thereby form a sputter film, so that the same film may be formed. Moreover, after the first sputter film is formed, the substrate 121 is not moved but is left to be placed in the same position as it is. Sputtering may be performed again after the elapse of a predetermined time, so that the same film may be formed.

In the embodiment, the two-layer films are formed by way of example, although even multi-layer films having three or more layers can be formed similarly. According to the embodiment, it is possible to form wiring having low electric resistance and no occurrence of hillock 70.

### Embodiment 2

An embodiment of an FED display unit including an MIM electron source 100 having a multi-layered bottom electrode 103 is now described.

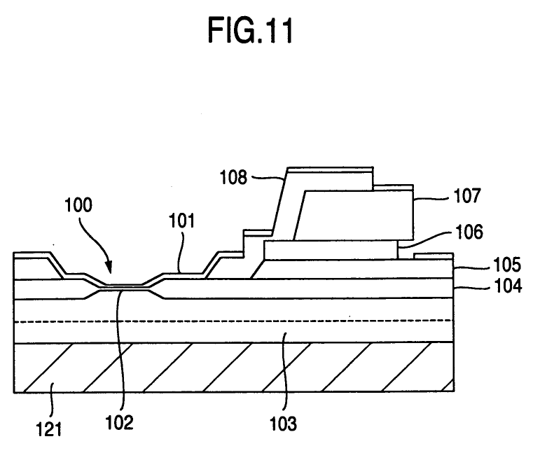

FIG. 11 is a sectional view schematically illustrating a display unit using an MIM type thin film electron source 100 according to the embodiment 2 of the present invention. A multi-layer Al—Nd bottom electrode 103 constituting data line connected to a data driver circuit, a top electrode 107 functioning as scan line connected to a scan line driver circuit and an electron source 100 emitting electrons are formed on a glass substrate 121. The electron source 100 is disposed on a multi-layer Al—Nd bottom electrode 103 (data line) and emits electrons by applying a voltage to the multi-layer Al—Nd bottom electrode 103 (data line) through a tunneling insulator 102 and an Au/Pt/Ir thin film electrode 101 connected to a top electrode 107 (scan line) through a contact electrode 108.

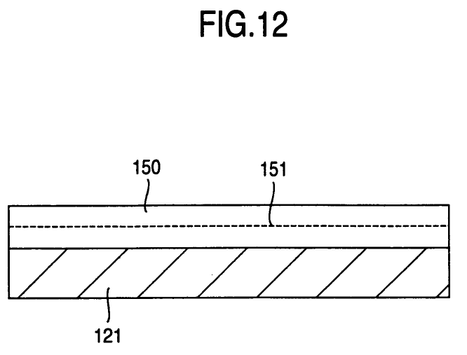

An embodiment of a method of manufacturing a display unit using the MIM type thin film electron source 100 of the present invention is now described with reference to FIGS. 12 to 18. As shown in FIG. 12, an aluminum alloy multi-layer film 150 constituting the bottom electrode 103 is deposited on an insulative substrate of glass. The deposit of the multi-layer film is performed by using the inline system sputtering equipped with a plurality of sputter targets 80 and making a substrate holder pass before the plurality of Al—Nd sputter targets 80 while maintaining the same deposit conditions (Ar gas pressure and deposit power) for each target. In the embodiment, the multi-layer film having 1, 2, 3 and 5 layers has been manufactured by way of trial while maintaining the thickness of all films to be the same, so that stress applied on the film can be uniformed and management of the manufacturing process can be facilitated by making the thickness of each film be identical.

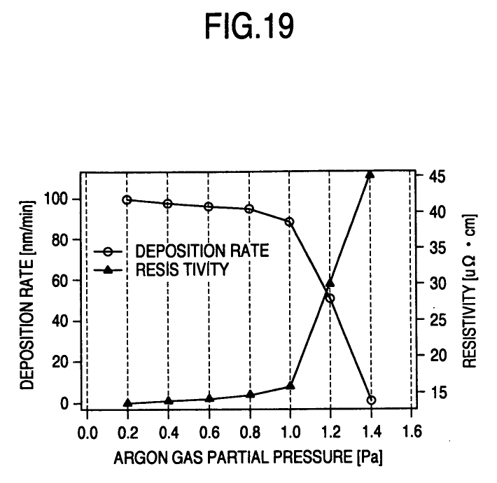

The sputter target 80 is made of Al-2 at. % Nd alloy and argon (Ar) gas pressure is lower than or equal to 1 Pa in order to suppress involution of Ar and form minute film. FIG. 19 shows the sputter deposit rate and the resistivity of the deposited Al—Nd film versus the Ar gas pressure. When the Ar gas pressure is lower than or equal to 1 Pa, the deposit rate and the resistivity are almost the same or hardly changed, although when it is higher than 1 Pa, the deposit rate is reduced and the resistivity is increased due to scattering by Ar gas. Accordingly, in order to form minute film, it is desirable that deposit is made under Ar gas partial pressure lower than or equal to 1 Pa and in the embodiment the Ar gas partial pressure is set to 0.4 Pa. The power density is set to be smaller than or equal to 3.2 W/cm² in order to prevent splash of Nd. The component of Nd in the Al—Nd film formed in this manner is 2%±0.2%.

An element which is not solidly solubilized with aluminum is effective as the additional element 50. The reason using the element which is not solidly solubilized is that the lower the solid solubility of the additional element 50 is, the easier the additional element 50 is educed and it is effective that the additional element 50 is segregated at the interface 151 by migration upon sputtering. Concretely, the additional element 50 may be not only rare earth elements such as Nd and Ce but also high melting point transition metals such as Ta, noble metals such as Pd, and Cu, Si, etc. The rare earth elements such as Nd among them is particularly effective since intermetallic compounds are produced and educed with aluminum at low temperature, for example, eduction is made at about 300° C. in case of Nd, whereas eduction is made at about 475° C. in case of Ta of the high melting point transition metals, for example.

After deposit, the stripe-shaped bottom electrode 103 is formed by the patterning process and the etching process. In the case of the display unit of the embodiment, the bottom electrode 103 constitutes the data line. Wet etching in mixed solution of phosphoric acid, acetic acid and nitric acid, for example, is used for etching of Al alloy. A light exposure apparatus or a printing method is used to make patterning of a resist for forming this electrode.

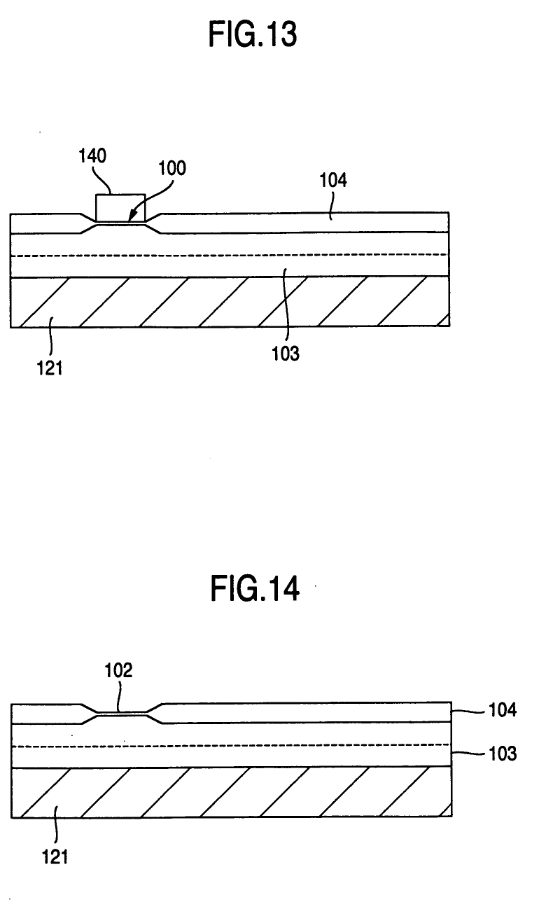

Next, the electron source 100 formed of the tunneling insulator 102 of an anodic oxidized layer and a thick field insulator 104 of an anodic oxidized layer are formed on the bottom electrode 103. First, part in which the electron source 100 is formed, of the bottom electrode 103 shown in FIG. 13 is masked by resist film 140 and other part is anodically oxidized to be thick selectively, so that the field insulator 104 is formed. An anodization voltage for the anodic oxidization is set to about 200 volts, so that the field insulator 104 having the thickness of about 270 nm is formed. Thereafter, the resist film 140 is removed and the remaining part is subjected to anodic oxidization using the anodization voltage of about 6 volts, so that the tunneling insulator 102 having the thickness of about 10 nm is made to grow. This state is shown in FIG. 14.

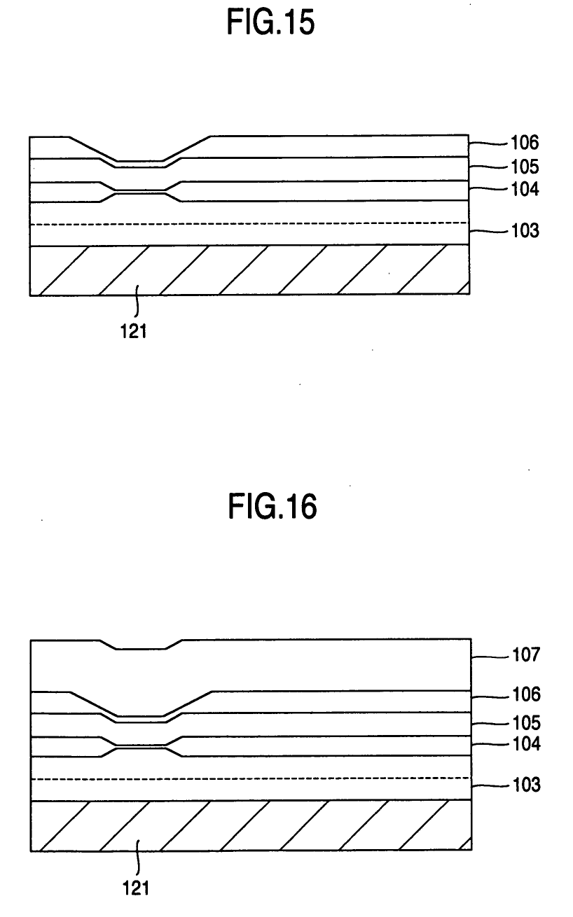

As shown in FIG. 15, a silicon (Si) layer 106 for separating the interlayer insulator 105 (SiN) and the Au/Pt/Ir thin film electrode 101 is deposited on the anodic oxidized layer by sputtering. Each layer is formed using the sputtering method but the interlayer insulator 105 is deposited by the reactive sputtering using Ar and N₂ as deposit gas. The thickness of both the interlayer insulator 105 and the silicon separation layer 106 is equal to 200 nm. Next, as shown in FIG. 16, a supply line of the electron source 100 and an Al/Al—Nd layer constituting the scan line in the embodiment are deposited by the sputtering method to have the thickness of 4.0 μm and 600 nm, respectively.

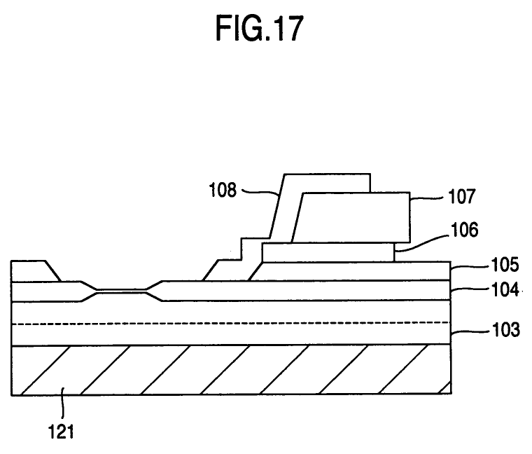

Thereafter, as shown in FIG. 17, the top electrode 107 is formed perpendicular to the bottom electrode 103 by the photo-etching process. Mixed solution of phosphoric acid, acetic acid and nitric acid, for example, is used for etching of the top electrode 107 in the same manner as the bottom electrode 103. Then, the silicon layer 106 and the interlayer insulator 105 (SiN) are etched selectively using the dry etching to make patterning. Mixed gas having CF₄ or SF₆, for example, as a main component is used as etching gas.

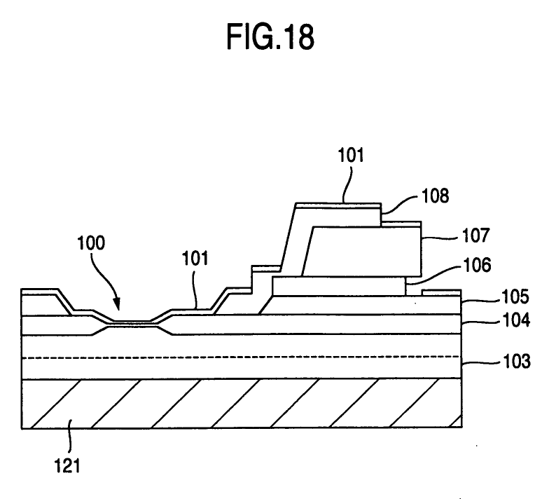

Subsequently, the Al—Nd layer is deposited with the thickness of 600 nm and is subjected to the same photo-etching process as the Al/Al—Nd top electrode 107 to form the contact electrode 108 for connecting the top electrode 107 and the Au/Pt/Ir electrode 101. Finally, as shown in FIG. 18, the interlayer insulator 105 and the silicon layer 106 are dry-etched to open an electron emission area and the Au/Pt/Ir thin film electrode 101 is deposited with the thickness of about 3 nm in total to thereby complete the electron source 100.

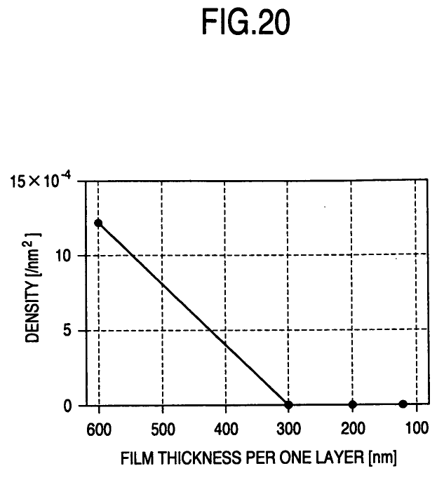

As described above, the MIM cathode in which formation of the hillock 70 on the bottom electrode 103 is suppressed and the heat tolerance is improved can be formed. The display unit of the embodiment has been manufactured by way of trial in the case where the total thickness of the bottom electrode 103 is 600 nm and the number of layers is 1, 2, 3 and 5. In this case, the film thickness is 600 nm for 1 layer, 300 nm for 2 layers, 200 nm for 3 layers and 120 nm for 5 layers. The dependence on the film thickness per layer of the density of hillocks in number in the bottom electrode 103 of the electron source 100 of the MIM cathode having the layers subjected to annealing is shown in FIG. 20. In the annealing, heating has been made during 30 minutes at temperature of 450° C.

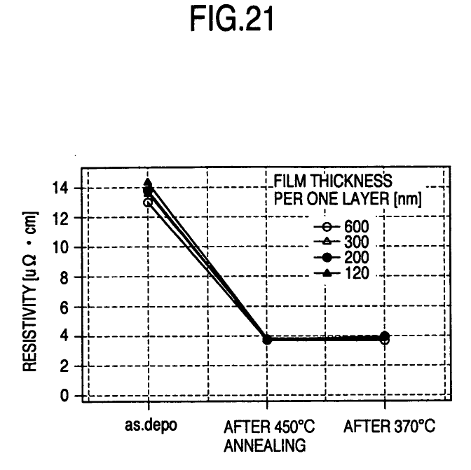

The density of hillocks in number is high for the thickness per layer of 600 nm, whereas the density of hillocks 70 in number is lowered for the thickness thinner than or equal to 300 nm and has no problem actually. Furthermore, as shown in FIG. 21, it is confirmed that the resistivity of the bottom electrode 103 is hardly changed even when the thickness per layer is reduced. Consequently, it has been proved that there can be provided the display unit in which formation of the hillock 70 is suppressed while maintaining the low resistivity by forming the bottom electrode 103 into the multi-layer film structure.

The reason that formation of hillock 70 can be suppressed in the embodiment of the present invention is described. The Al hillock 70 is an educt formed by annealing metal having a low melting point and its structure is a collection of pure Al grains 60 as shown in FIG. 7. Accordingly, in order to prevent formation of hillock 70, it is necessary to adopt the structure in which the Al grains 60 are dispersed within the film and the hillock is not oversized.

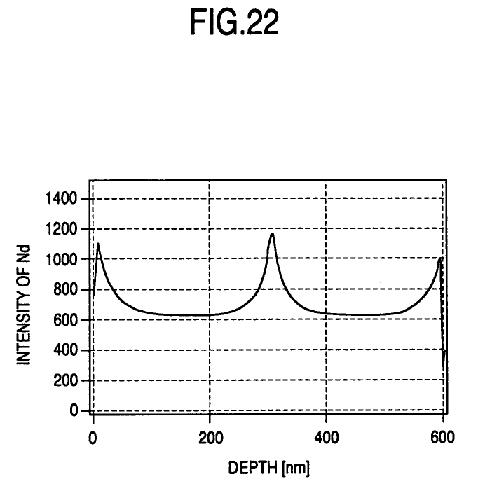

Accordingly, in order to exemplify the validity of the present invention, a measured result of a depth profile in the depth direction of the additional element Nd by the secondary ion mass spectrometry (SIMS) is shown in FIG. 22. The additional element Nd is dispersed substantially uniformly within the film in case of a single-layer film, whereas the density of Nd is increased in the proximity of the interface in case of two-layer film. This reason is that Nd which is not solidly solubilized with host metal Al is self-scattered and captured near the interface having low potential to be segregated. Consequently, growth of pure Al grains 60 causing formation of hillock is impeded, so that formation of hillock after annealing can be prevented.

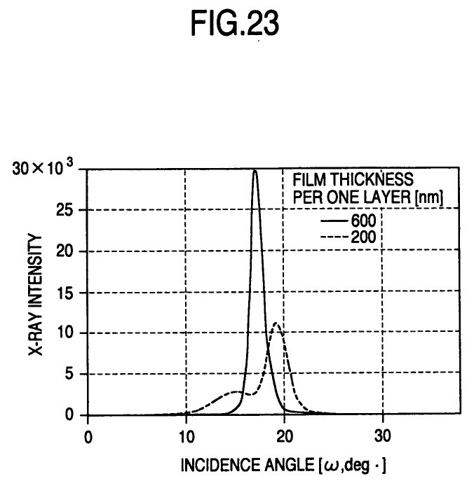

FIG. 23 shows the orientation of the multi-layer film by the X-ray diffraction (XRD). In FIG. 23, a solid line represents a single-layer film having the thickness of 600 nm and a dotted line represent a multi-layer film composed of three layers each having the thickness of 200 nm. In the single-layer film, X-rays are diffracted in the vicinity of the incidence angle of about 17° and in the three-layer film, X-rays are diffracted in two directions of about 17° and 19°. This reason is that the growing direction (orientation) of grains is different between the single-layer film which is directly deposited on the glass substrate and the three-layer film which is deposited on Al—Nd film after deposit is stopped once. Consequently, the diffusion route of aluminum is disconnected at the interface 151, so that formation of hillock after annealing can be prevented.

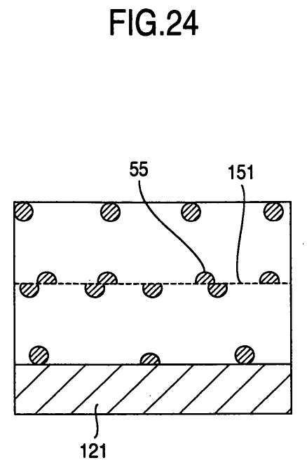

FIG. 24 is a sectional view schematically illustrating the interface shape of the multi-layer film by the scanning electron microscope. As shown in the section, segregated substances of the intermetallic compounds of Al—Nd are mainly distributed not only near the surface and the glass plane but also at the deposit interface and the interface 151 is formed of discontinuous grains. It can be confirmed from this result that growth of pure aluminum grains causing formation of hillock is impeded. Moreover, by arranging the film thickness of the multi-layer film, the sizes of grains can be made substantially identical on average although each size thereof is different, so that the stress causing formation of hillock is uniformed within the film. The size of grains can be estimated as follow. The Al—Nd multi-layer film is irradiated with parallel focused ion beam (FIB) in the normal direction of the film surface and the exposed section is observed by the transmission electron microscope (TEM) so that the diameter of grains is estimated.

### Embodiment 3

A display unit such as a liquid crystal display unit and an organic electroluminescent diode display unit includes a multiplicity of scan lines extending in the horizontal direction of a display screen and disposed in the vertical direction, a multiplicity of data lines extending in the vertical direction of the display screen and disposed in the horizontal direction and pixels formed in parts enclosed the scan lines and the data lines. Each of the pixels includes a pixel electrode and a thin film transistor (hereinafter referred to as TFT) for controlling supply of a picture signal to the pixel electrode.

The embodiment shows an example in case where the present invention is applied to the TFT. A manufacturing method of the display unit using TFT elements having the bottom electrode 103 of the present invention formed by multi-layer film is described with reference to FIGS. 25 to 30. First, as shown in FIG. 25, an aluminum alloy multi-layer film 150 constituting the bottom electrode 103 is deposited on an insulative substrate 121 of glass. Deposition of the multi-layer film is made by using the inline system sputtering equipped with a plurality of targets and making a substrate holder pass before plural Al—Nd targets while maintaining the same deposit conditions (Ar gas pressure and deposit power).

In the embodiment, the multi-layer film having 1, 2, 3 and 5 layers has been manufactured by way of trail and the thickness of each layer was made substantially identical for alleviation of the stress applied to the film and simplification of manufacturing processes. The sputter target 80 is made of Al-2 at. % Nd alloy and Ar gas pressure is set to be lower than or equal to 1 Pa in order to suppress involution of Ar and form minute film. In the embodiment, the Ar gas pressure is set to 0.4 Pa. The power density is set to be smaller than or equal to 3.2 W/cm² in order to prevent splash of Nd. The average density of Nd in the Al—Nd film formed in this manner is 2%±0.2%.

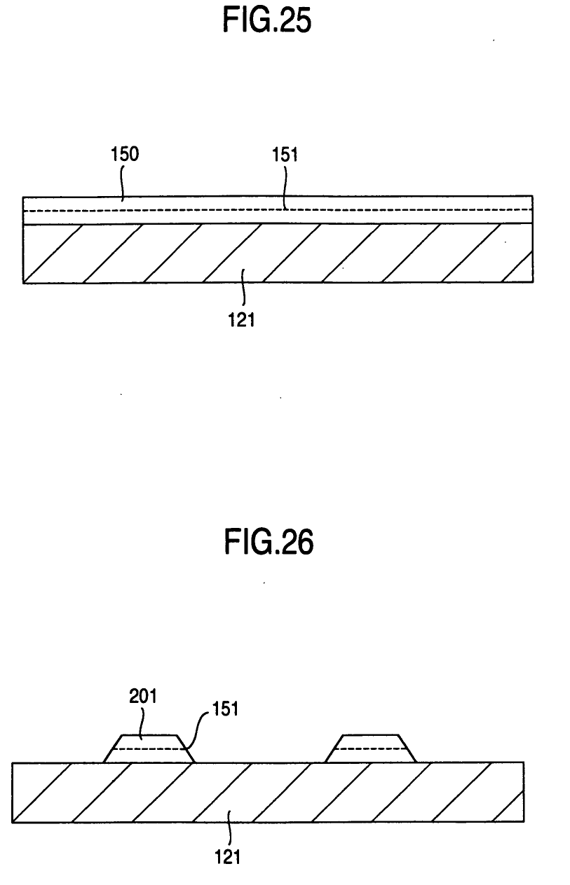

After deposit, as shown in FIG. 26, the stripe-shaped bottom electrode 103 is formed by the patterning process and the etching process. In the case of the display unit of the embodiment, the bottom electrode 103 constitutes a gate electrode 201. Wet etching in mixed solution of phosphoric acid, acetic acid and nitric acid, for example, is used for etching of Al alloy. The photolithograpy or printing method is used to make patterning of a resist for forming this electrode.

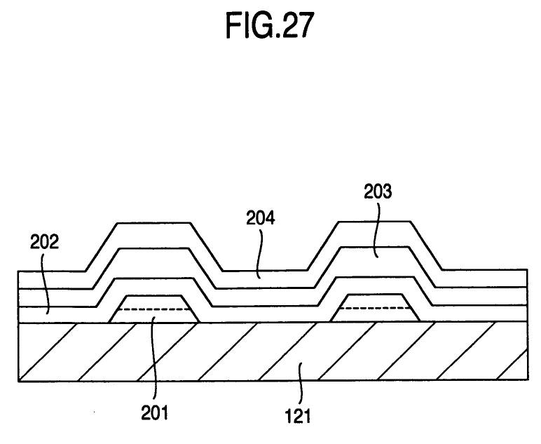

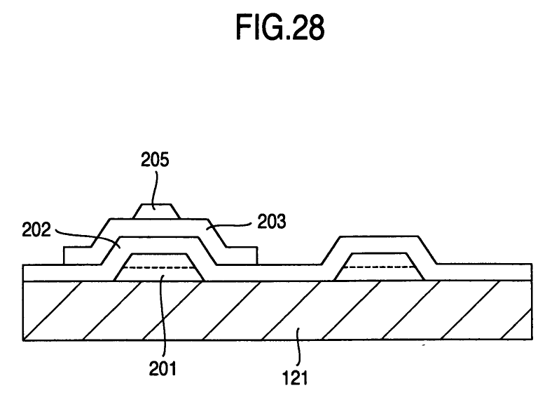

Next, as shown in FIG. 27, a silicon nitride film 204 constituting a gate insulator 202 is deposited on the bottom electrode (gate electrode 201) by the plasma-CVD. The thickness thereof is set to about 300 nm. Then, a hydrogenated amorphous silicon (a-Si:H) layer 203 and a silicon nitride (SiN) layer constituting a channel protection layer are deposited and subjected to the patterning process and the dry etching process to form a channel 205. This state is shown in FIG. 28. Mixed gas having CF₄ or SF₆, for example, as a main component is used as etching gas of the dry etching.

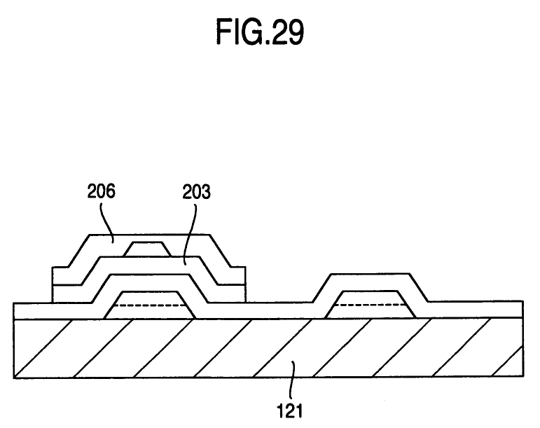

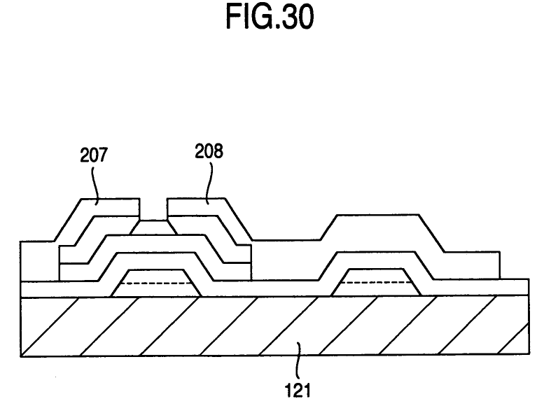

Moreover, n-type hydrogenated amorphous silicon (N+a-Si:H) 206 doped with phosphorus is deposited and is subjected to the patterning, so that n-type hydrogenated amorphous silicon layer 206 and hydrogenated amorphous silicon (a-Si:H) layer 203 are formed as shown in FIG. 29. Finally, as shown in FIG. 30, Al—Nd alloy film having the thickness of about 300 nm is deposited using the same inline system sputtering as the gate electrode 201 and is divided by patterning of photolithography to form a source electrode 207 and a drain electrode 208.

As described above, the TFT device in which formation of hillock 70 on the bottom electrode (gate electrode 201) is suppressed and the heat tolerance is improved can be fabricated. The display unit of the embodiment has been manufactured by way of trial in the case where the total thickness of the bottom electrode (gate electrode 201) is 600 nm and the number of layers is 1, 2, 3 and 5. In this case, the film thickness is 600 nm for 1 layer, 300 nm for 2 layers, 200 nm for 3 layers and 120 nm for 5 layers.

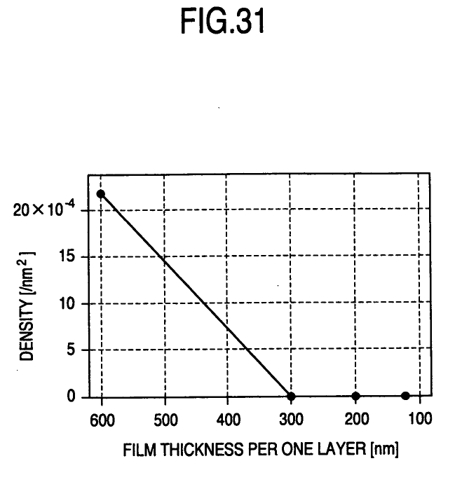

The dependence on the film thickness per layer of the density of hillocks in number in the gate electrode 201 of the TFT device subjected to annealing is shown in FIG. 31. In the annealing, heating has been made during 30 minutes at temperature of 450° C. similarly to the embodiment 1. The density of hillocks in number is high for the film thickness per layer of 600 nm, whereas the density of hillocks 70 in number is lowered for the film thickness thinner than or equal to 300 nm and has no problem actually. Furthermore, as confirmed in FIG. 19, the resistivity of the bottom electrode 103 is hardly changed even when the film thickness per layer is reduced. Consequently, it has been proved that there can be provided the display unit in which formation of the hillock 70 is suppressed while maintaining the low resistivity by forming the bottom electrode 103 of the TFT device into the multi-layer film structure.

### Embodiment 4

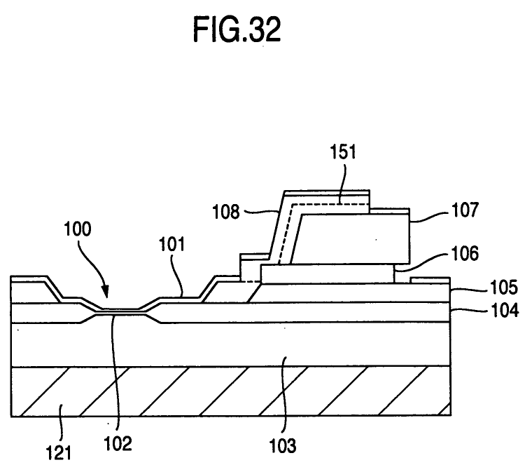

A display unit of the embodiment includes an MIM type cathode having a contact electrode 108 formed into a multi-layer film structure. FIG. 32 is a sectional diagram schematically illustrating the display unit using an MIM type thin film electron source 100 according to the embodiment 4 of the present invention. A bottom electrode 103 constituting the data line connected to a data line driving circuit, a top electrode 107 constituting the scan line connected to the scan line driving circuit and an electron source 100 emitting electrons are formed on a glass substrate 121. The electron source 100 is disposed on the bottom electrode 103 (data line) and emits electrons by applying a voltage to the bottom electrode 103 (data line) through a tunneling insulator 102 and an Au/Pt/Ir thin film electrode 101 connected to the top electrode 107 (scan line) through the multi-layer contact electrode 108.

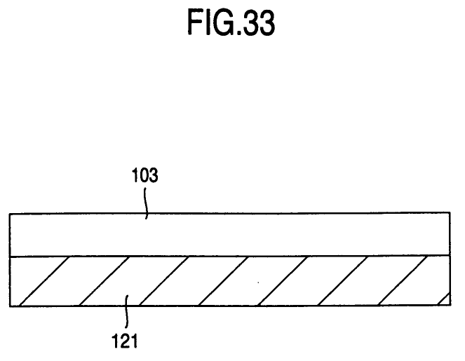

An embodiment of a method of manufacturing the display unit using the MIM type thin film electron source 100 of the present invention is now described with reference to FIGS. 33 to 39. As shown in FIG. 33, an aluminum alloy film constituting the bottom electrode 103 is deposited on an insulative substrate 121 of glass. The deposit of the film is made by using the inline system sputtering. In the embodiment, the number of layers for the bottom electrode 103 is 1 different from the embodiment 1 and target is made of Al-2 at. % Nd alloy.

Ar gas pressure is set to be lower than or equal to 1 Pa in order to suppress involution of Ar in the same manner as the embodiment 1 and form minute film. In the embodiment, the Ar gas pressure is set to 0.4 Pa. The power density is set to be smaller than or equal to 3.2 W/cm² in order to prevent splash of Nd. The average density of Nd in the Al—Nd film formed in this manner is 2%±0.2%.

An element which is not solidly solubilized with aluminum in the same manner as the embodiment 1 is effective as the additional element 50. The reason using the element which is not solidly solubilized is that the lower the solid solubility of the additional element 50 is, the easier the additional element 50 is educed and it is effective that the additional element 50 is segregated at the interface 151 by migration upon sputtering. Concretely, the additional element 50 may be not only rare earth elements such as Nd and Ce but also high melting point transition metals such as Ta, noble metals such as Pd, and Cu, Si, etc. The rare earth elements such as Nd among them is particularly effective since intermetallic compounds are produced and educed with aluminum at low temperature, for example, eduction is made at about 300° C. in case of Nd, whereas eduction is made at about 475° C. in case of Ta of the high melting point transition metals, for example.

After deposit, the stripe-shaped bottom electrode 103 is formed by the patterning process and the etching process. In the case of the display unit of the embodiment, the bottom electrode 103 constitutes the data line. Wet etching in mixed solution of phosphoric acid, acetic acid and nitric acid, for example, is used for etching of Al alloy. A light exposure apparatus or a printing method can be used to make patterning of a resist for forming this electrode.

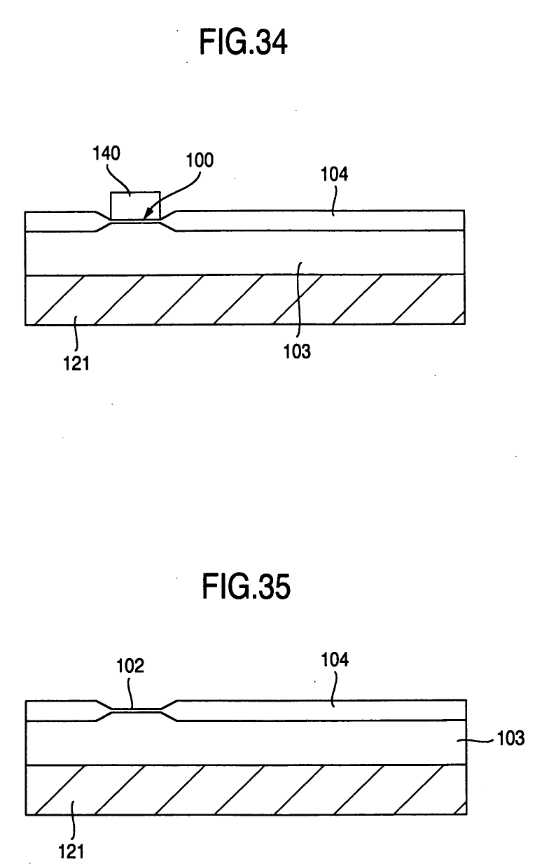

Next, the electron source 100 formed of the tunneling insulator 102 of an anodic oxidized layer and a thick field insulator 104 of an anodic oxidized layer are formed on the bottom electrode 103. First, as shown in FIG. 34, part in which the electron source 100 is formed, of the bottom electrode 103 is masked by resist film 140 and other part is anodically oxidized to be thick selectively, so that the field insulator 104 is formed. An anodization voltage for the anodic oxidization is set to about 200 volts, so that the field insulator 104 having the thickness of about 270 nm is formed. Thereafter, the resist film 140 is removed and the remaining part is subjected to anodic oxidization using the anodization voltage of about 6 volts, so that the tunneling insulator 102 having the thickness of about 10 nm is made to grow. This state is shown in FIG. 35.

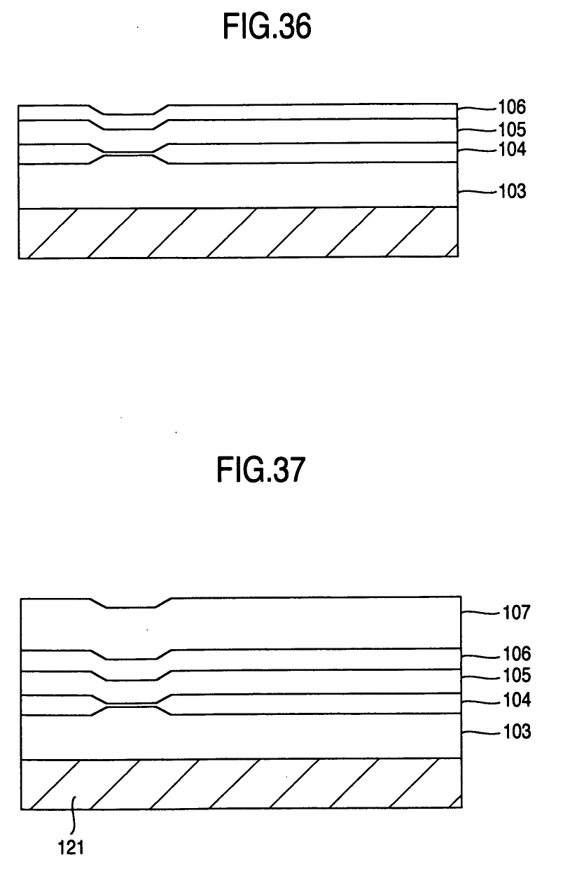

Then, as shown in FIG. 36, a silicon layer 106 for separating the interlayer insulator 105 (SiN) and the Au/Pt/Ir thin film electrode is deposited thereon by sputtering. Each layer is formed using the sputtering method but the interlayer insulator 105 is deposited by the reactive sputtering using Ar and N₂ as deposit gas. The thickness of both the interlayer insulator 105 and the silicon separation layer 106 is equal to 200 nm. Subsequently, the silicon layer 106 and the interlayer insulator 105 (SiN) are etched selectively using the dry etching to make patterning. Mixed gas having CF₄ or SF₆, for example, as a main component is used as etching gas.

Next, as shown in FIG. 37, a supply line of the electron source 100 and an Al/Al—Nd layer constituting the scan line in the embodiment are deposited by sputtering to have the thickness of 4.0 μm and 600 nm, respectively. The top electrode 107 is formed perpendicular to the bottom electrode 103 by the photo-etching process. Mixed solution of phosphoric acid, acetic acid and nitric acid, for example, is used for etching of the top electrode 107 in the same manner as the bottom electrode 103. Then, the silicon layer 106 and the interlayer insulator (SiN) 105 are etched selectively using the dry etching to make patterning. Mixed gas having CF₄ or SF₆, for example, as a main component is used as etching gas.

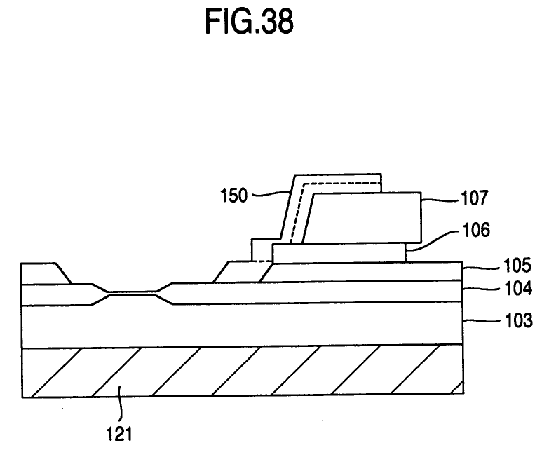

Subsequently, the Al—Nd layer is deposited to have the thickness of 600 nm and is subjected to the same photo-etching process as the Al/Al—Nd top electrode 107 to form the contact electrode 108 for connecting the top electrode 107 and the Au/Pt/Ir electrode 101. This state is shown in FIG. 38. However, this embodiment is different from the embodiment 1 and in order to suppress formation of hillock on the contact electrode, the Al—Nd film constituting the contact electrode 108 is formed into the multi-layer film structure. The number of layers thereof is 1, 2, 3 and 5 in the same manner as the embodiment 1 and the film thickness of each layer is set to be substantially identical. Other deposit conditions are set to be the same as the bottom electrode 103 of the embodiment 1 and the multi-layer film is deposited by using the inline system sputtering equipped with a plurality of sputter targets 80 and making a substrate holder pass before the plurality of Al—Nd targets while maintaining the same deposit conditions (Ar gas pressure and deposit power) for each target.

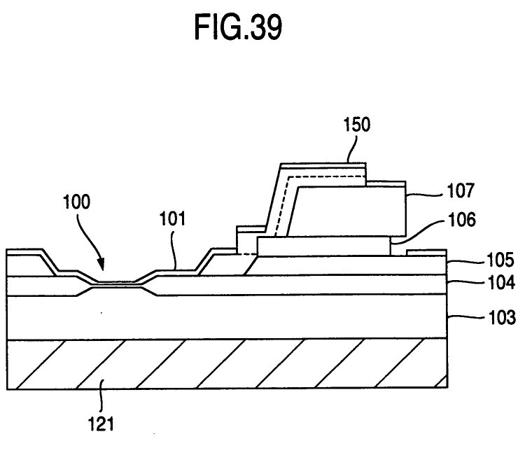

The target is made of Al-2 at. % Nd alloy and the gas pressure is set to be lower than or equal to 0.4 Pa. The power density is set to 3.2 W/cm². Then, the interlayer insulator 105 and the silicon layer 106 are dry-etched to open an electron emission part. Finally, as shown in FIG. 39, the Au/Pt/Ir thin film electrode 101 is deposited to have the thickness of about 3 nm in total to complete the electron source 100. The average density of Nd in the contact electrode formed in this manner is 2%±0.2%.

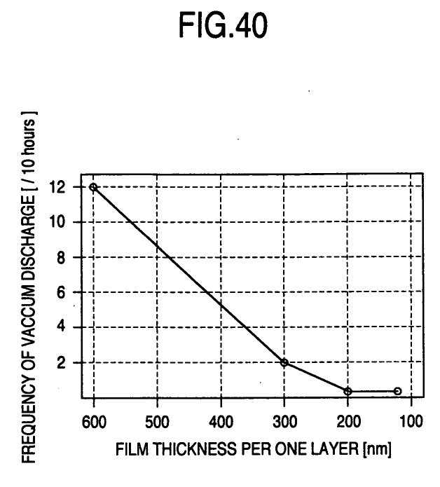

As described above, formation of hillock 70 on the top electrode can be suppressed and the MIM cathode having improved heat tolerance can be manufactured. FIG. 40 shows the dependence on the film thickness of the frequency of discharges of the contact electrode 108 and the anode plate 130 in the MIM-FED. The dependence of FIG. 4 is estimated for the MIM-FED which has been manufactured by way of trial in the case where the film thickness of the contact electrode 108 is 600 nm in total and the number of layers is 1, 2, 3 and 5. In this case, the film thickness is 600 nm for 1 layer, 300 nm for 2 layers, 200 nm for 3 layers and 120 nm for 5 layers. When the film thickness per layer is 600 nm, discharge is made 12 times in 10 hours, whereas when the film thickness is thinner than or equal to 300 nm, the frequency of discharges is reduced, so that the validity of the present invention can be proved.

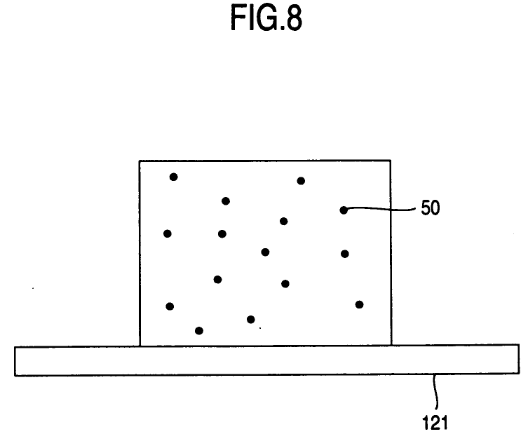

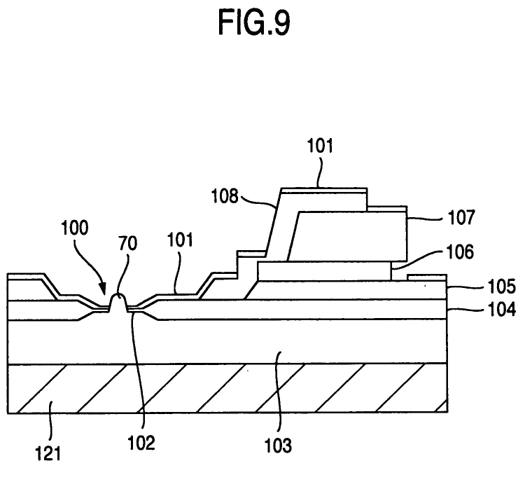

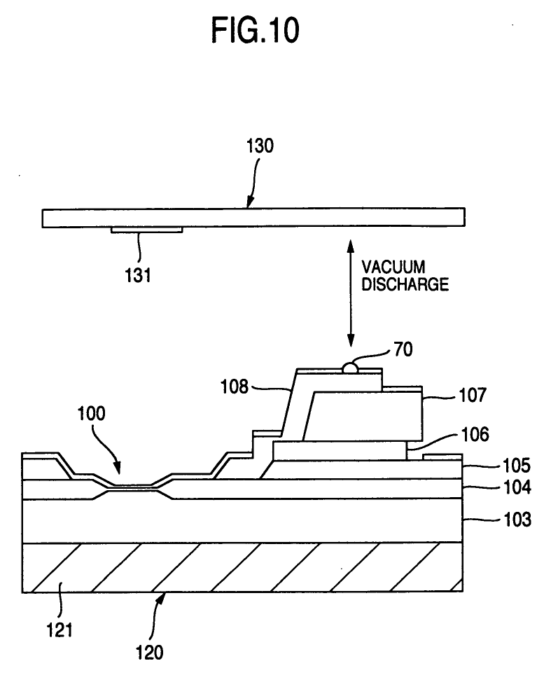

The embodiments 1 to 4 of the present invention have been described in detail with reference to FIGS. 1 to 40. In the embodiments, the FED having the MIM type electron source and the TFT device are used, although the present invention can be applied to even other wiring using Al alloy and other display units but is not limited thereto.

1. A display unit including scan lines extending in a first direction of a display screen and disposed in a second direction perpendicular to the first direction, data lines extending in the second direction of the display screen and disposed in the first direction, insulator film formed between the scan lines and the data lines and pixel electrodes formed in parts enclosed by the scan lines and the data lines, wherein
the scan lines or the data lines contain a plurality of aluminum alloy layers and the plurality of aluminum alloy layers contain the same additional element.

2. A display unit according to claim 1, wherein the plurality of aluminum alloy layers contain the same component.

3. A display unit according to claim 1, wherein the thickness of each of the plurality of aluminum alloy layers is thinner than or equal to 300 nm.

4. A display unit according to claim 1, wherein the thickness of each of the plurality of aluminum alloy layers is substantially identical.

5. A display unit according to claim 1, wherein the additional element contained in the plurality of aluminum alloy layers is an element which is not solidly solubilized with aluminum.

6. A display unit according to claim 1, wherein the plurality of aluminum alloy layers contain Nd (neodymium) or another rare earth element.

7. A display unit according to claim 1, wherein the plurality of aluminum alloy layers contain high-melting point transition metals such as Ta, noble metals such as Pd, or another element such as Cu and Si.

8. A display unit according to claim 1, wherein the plurality of aluminum alloy layers have different orientations.

9. A display unit according to claim 1, wherein the density of the additional element at an interface between first and second aluminum alloy layers of the plurality of aluminum alloy layers is higher than that of the additional element in the first or second aluminum alloy layer.

10. A display unit according to claim 1, wherein a discontinuous interface of a grain boundary is formed at an interface of first and second aluminum alloy layers of the plurality of aluminum alloy layers.

11. A display unit including scan lines extending in a first direction of a display screen and disposed in a second direction perpendicular to the first direction, data lines extending in the second direction of the display screen and disposed in the first direction, insulator film formed between the scan lines and the data lines, pixel electrodes and thin film transistors formed in parts enclosed by the scan lines and the data lines, gate electrodes of the thin film transistors connected to the scan lines, source electrodes of the thin film transistors connected to the data lines and drain electrodes of the thin film transistors connected to the pixel electrodes, wherein
the gate electrodes of the thin film transistors contain a plurality of aluminum alloy layers and the plurality of aluminum alloy layers contain the same additional element.

12. A display unit according to claim 11, wherein the plurality of aluminum alloy layers contain the same component.

13. A display unit according to claim 11, wherein the thickness of the plurality of aluminum alloy layers is thinner than or equal to 300 nm.

14. A display unit according to claim 11, wherein the additional element contained in the plurality of aluminum alloy layers is an element which is not solidly solubilized with aluminum.

15. A display unit including a cathode plate having electron sources formed into a matrix and an anode plate in which a fluorescent screen is formed, the cathode plate and the anode plate being disposed with predetermined space therebetween, wherein
the electron source comprises a bottom electrode formed of a plurality of aluminum alloy layers, a tunneling insulator and an electrode formed of thin film metal layer and the plurality of aluminum alloy layers contain the same additional element.

16. A display unit according to claim 15, wherein the plurality of aluminum alloy layers contain the same component.

17. A display unit according to claim 15, wherein the thickness of the plurality of aluminum alloy layers is thinner than or equal to 300 nm.

18. A display unit according to claim 15, wherein the additional element contained in the plurality of aluminum alloy layers is an element which is not solidly solubilized with aluminum.

19. A display unit including scan lines extending in a first direction of a display screen and disposed in a second direction perpendicular to the first direction, data lines extending in the second direction of the display screen and disposed in the first direction, insulator film formed between the scan lines and the data lines and electron sources formed near intersections of the scan lines and the data lines, wherein
the electron source includes a bottom electrode formed of aluminum alloy layer, a tunneling insulator and an electrode formed of thin film metal layer, and
the data lines are connected to the bottom electrodes, the scan lines being connected to the electrodes formed of the thin film metal layers constituting the electron sources through contact electrodes, the contact electrode being formed of a plurality of aluminum alloy layers, the plurality of aluminum alloy layers containing the same additional element.

20. A display unit including scan lines extending in a first direction of a display screen and disposed in a second direction perpendicular to the first direction, data lines extending in the second direction of the display screen and disposed in the first direction, insulator film formed between the scan lines and the data lines and pixel electrodes formed in parts enclosed by the scan lines and the data lines, wherein
the scan lines or the data lines contain a plurality of aluminum alloy layers and the plurality of aluminum alloy layers are formed by sputtering aluminum alloy target, the plurality of aluminum alloy layers being sputtered at predetermined intervals.

21. A display unit according to claim 20, wherein the sputtering is performed by installing a plurality of targets in a vacuum chamber and moving a substrate of the display unit within the chamber so that sputtering is performed each time the substrate is opposed to the target, so that the plurality of aluminum alloy layers are formed.

22. A display unit according to claim 20, wherein the sputtering is performed by installing a single target in a vacuum chamber and moving a substrate of the display unit within the chamber so that sputtering is performed each time the substrate is opposed to the target, so that the plurality of aluminum alloy layers are formed.

23. A display unit according to claim 20, wherein the sputtering is performed under argon gas partial pressure lower than or equal to 1 Pa.
